(19) United States
(12) Patent Application Publication
(10) Pub. No.: US 2017/0250546 A1
(43) Pub. Date: Aug. 31, 2017

(54) POWER DEVICE, STORAGE DEVICE AND POWER DEVICE CONTROL METHOD

(71) Applicant: FUJITSU LIMITED, Kawasaki-shi (JP)

(72) Inventor: Ikki Okashita, Kawasaki (JP)

(73) Assignee: FUJITSU LIMITED, Kawasaki-shi (JP)

(21) Appl. No.: 15/370,387

(22) Filed: Dec. 6, 2016

(30) Foreign Application Priority Data
Feb. 25, 2016 (JP) 2016-034438

(51) Int. Cl. H02J 7/00; G11C 5/14; G01R 31/36

(52) U.S. Cl. CPC H02J 7/0016; H02J 7/0026; G01R 31/3679; G11C 5/141; H02J 7/345

(57) ABSTRACT

A power device includes a lithium ion capacitor and a regenerative LIC whose capacity is lower than that of the lithium ion capacitor. The power device further includes a diagnosis circuit and a charge circuit. The diagnosis circuit performs a life diagnosis on the lithium ion capacitor by using electricity that is discharged from the lithium ion capacitor and charges the regenerative LIC with the electricity used for the life diagnosis. The charge circuit charges the lithium ion capacitor with the electricity that is output from the regenerative LIC.

### CROSS-REFERENCE TO RELATED APPLICATION

This application is based upon and claims the benefit of priority of the prior Japanese Patent Application No. 2016-034438, filed on Feb. 25, 2016, the entire contents of which are incorporated herein by reference.

### FIELD

The embodiments discussed herein are related to a power device, a storage device and a power supply control method.

### BACKGROUND

As various types of data are computerized and dealt with on computers recently, the importance of storage devices, such as a disk-array device, independent of a computer and capable of storing a large volume of data efficiently is increasing. Introducing the RAID (Redundant Arrays of Inexpensive Disks) technology to disk array devices increases its reliability compared to simple disk array devices. Furthermore, in general, incorporation of a cache memory shortens the time to access data.

Furthermore, logical data protection with, for example, the RAID technology has to be implemented and ways to increase reliability with respect to physical and electric aspects have to be contrived. For example, a cache memory is a volatile memory that loses stored data when the power supply is lost. To deal with this, there is a technology not to lose data under process stored in a cache memory when a power failure occurs.

In order to protect data when a power failure occurs, for example, a storage device includes a lithium ion capacitor (LIC). Upon detecting a power failure, the storage device switches the power to the LIC. The controller (controller module (CM)) for disk control uses the power supplied from the lithium ion capacitor to stop the process under execution and copies the data in the cache memory to be lost due to the stop of power supply into, for example, a non-volatile memory to protect the data. There is, as another method, a technology of, when a power failure occurs, causing transition of a cache memory to a low-power mode and keeping data stored by using power supplied from a lithium ion capacitor.

When a battery, such as a lithium ion capacitor, is used as a measure to protect data when a power failure occurs as described above, the battery is expected to run normally when a power failure occurs; however, deterioration of the battery occurs due to repetition of charging and discharging. In order for the battery to run normally when a power failure occurs, a constant life diagnosis on the battery is performed to know the state of the battery.

There is the following technology as a technology of determining whether a battery deteriorates. For example, there is a conventional technology of detecting an internal resistance and a capacitance, on discharge, of a lithium ion capacitor that stores a regenerative energy of a vehicle and determining whether the capacitor deteriorates.

There is another conventional technology of detecting a high-rate deterioration where the internal resistance increases due to distribution of salinity in a secondary battery from the internal resistance of the secondary battery and charging the secondary battery compulsory after storing electricity in an auxiliary power.

There is still another conventional technology of switching between switches provided in multiple lithium batteries to connect a lithium battery to a capacitor, balancing the voltage between the lithium battery and the capacitor, and measuring the voltage of the battery after the voltage is balanced to determine whether the battery deteriorates.

Patent Document 1: Japanese Laid-open Patent Publication No. 2013-233011

Patent Document 2: Japanese Laid-open Patent Publication No. 2013-46446

Patent Document 3: Japanese Laid-open Patent Publication No. 2010-246214

When a life diagnosis is performed on a battery, however, electricity is discharged from the batter. In order to perform constant life diagnoses with high degree of certainty over a long term on, for example, a battery mounted on a storage device, a large volume of electricity is emitted from the battery. For this reason, the energy loss in the storage device due to the life diagnosis on the battery increases and this hinders reduction of the power consumption.

Even with the conventional technology of determining whether a capacitor that stores the regenerative energy of a vehicle deteriorates from the internal resistance, etc., on discharge, of the capacitor, it is difficult to reduce power consumption because the power used for deterioration diagnosis is consumed. Furthermore, even with the conventional technology of detecting high-rate deterioration and compulsory charging a secondary battery, it is difficult to reduce power consumption because no consideration is paid to the power used for normal deterioration diagnosis. Furthermore, even with the conventional technology of measuring the battery voltage after the voltage is balanced, it is difficult to reduce power consumption because the power for deterioration diagnosis is consumed.

### SUMMARY

According to an aspect of an embodiment, a power device includes: a primary battery; a secondary battery whose capacity is lower than that of the primary battery; a diagnosis unit that performs a life diagnosis on the primary battery by using electricity that is discharged from the primary battery and charges the secondary battery with the electricity used for the life diagnosis; and a charge unit that charges the primary battery with the electricity that is output from the secondary battery.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of an overview of a storage device according to an embodiment;

FIG. 2 is a block diagram of a power device; and

FIG. 3 is a flowchart of a life diagnosis process performed by the power device of the embodiment.

### DESCRIPTION OF EMBODIMENT

Preferred embodiments of the present invention will be explained with reference to accompanying drawings. Note that the embodiments do not limit the power device, the storage device, and the power device control method disclosed herein.

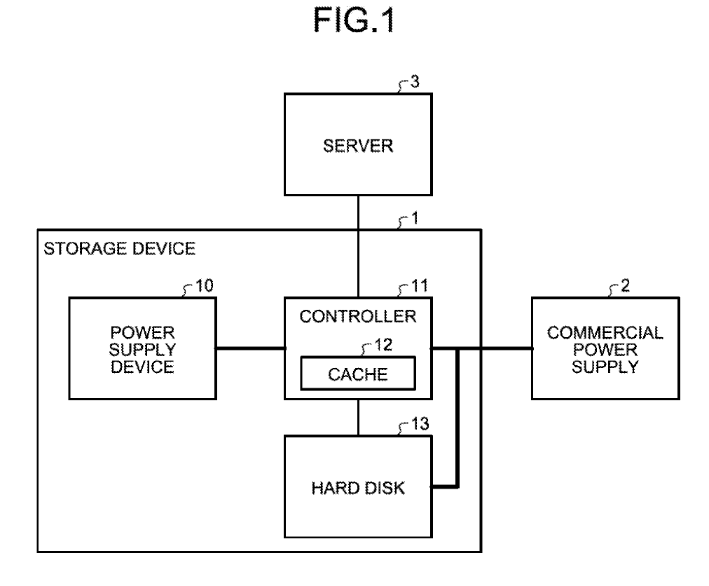

FIG. 1 is a block diagram of an overview of a storage device according to an embodiment. The bold line in FIG. 1 represents a power supply system and a thin line represents a signal communication path.

As illustrated in FIG. 1, a storage device 1 includes a power supply device 10, a controller 11, and a hard disk 13. The hard disk 13 is a data storage and is supplied with power from a commercial power supply 2 to run.

The controller 11 is supplied with power from the commercial power supply 2. When the power supply from the commercial power supply 2 stops due to, for example, a power failure, the controller 11 switches the power to be supplied with power from the power supply device 10. The controller 11 runs with the power supplied from the commercial power supply 2 or the power supply device 10.

The controller 11 includes a cache 12. The controller 11 further includes a central processing unit (CPU) and a non-volatile memory (not illustrated). The cache 12 is a volatile memory. The controller 11 is connected to a server 3 and the hard disk 13. The following process is implemented by the CPU of the controller 11.

When there is a power supply from the commercial power supply 2, the controller 11 receives a data read/write instruction from the server 3. The controller 11 uses the cache 12 to read or write data from or to the hard disk 13 according to the instruction. For example, when reading data from the hard disk 13, the controller 11 determines whether data to be read is in the cache 12. When the data is in the cache 12, the controller 11 reads the data from the cache 12 and transmits the read data to the server 3. When the data is not in the cache 12, the controller 11 reads the data from the hard disk 13 and transmits the read data to the server 3 and stores the data in the cache 12.

When the power supply from the commercial power supply 2 stops and the power is switched to a power supply to from the power supply device 10, the controller 11 transfers the data stored in the cache 12 to the non-volatile memory of the controller 11. Accordingly, the data stored in the cache 12 is not lost and is stored in the controller 11. When power supply from the commercial power supply 2 is restored, the controller 11 reads the data stored in the non-volatile memory into the cache 12 and restarts the process that is executed before the stop of the power supply from the commercial power supply 2.

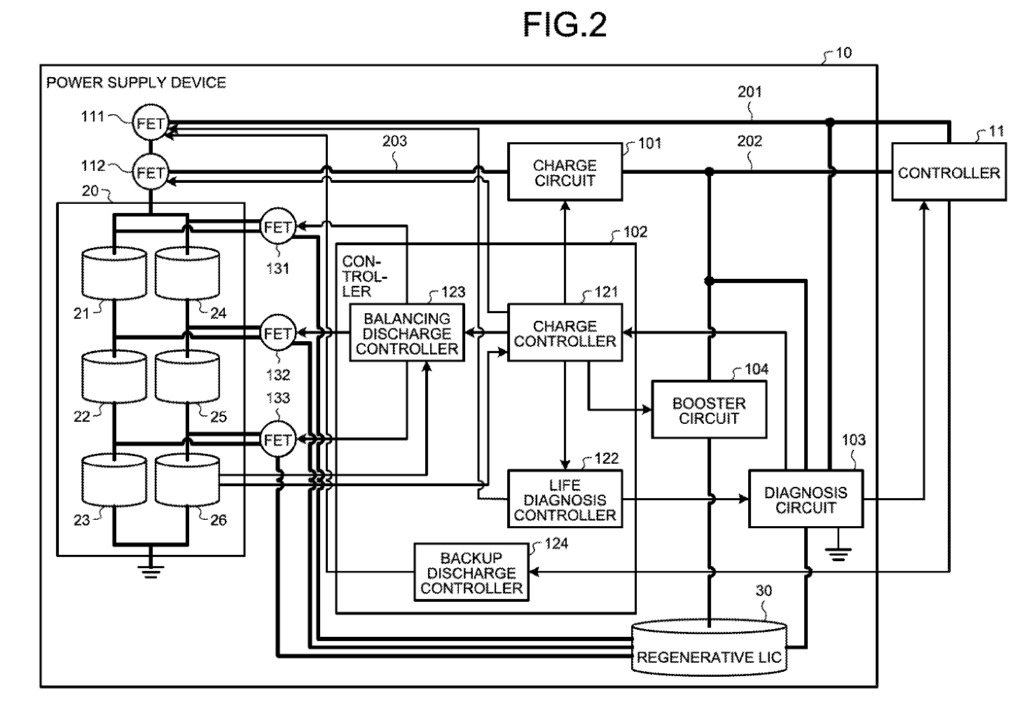

With reference to FIG. 2, details of the power supply device 10 will be described. FIG. 2 is a block diagram of the power device.

The power supply device 10 includes a charge circuit 101, a controller 102, a diagnosis circuit 103, and a booster circuit 104. The power supply device 10 includes FET switches 111, 112 and 131 to 133. The power supply device 10 further includes lithium ion capacitors 21 to 26 and a regenerative LIC 30.

The lithium ion capacitors 21 to 26 are chargeable batteries having the same capacity. The lithium ion capacitors 21 to 26 are backup powers that supply power to the controller 11 when, for example, a power failure occurs. When the lithium ion capacitors 21 to 26 are collectively dealt with as a single lithium ion capacitor, they are referred to as a “lithium ion capacitor 20”. The lithium ion capacitor 20 serves as an exemplary “first battery”.

According to the embodiment, the lithium ion capacitors 21 to 23 are connected in series and the lithium ion capacitors 24 to 26 are connected in series. The lithium ion capacitors 21 to 23 and the lithium ion capacitors 24 to 26 are connected in parallel. One end of the lithium ion capacitors 21 to 26 is grounded. The other end of the lithium ion capacitors 21 to 26 is connected to the FET switch 112.

The regenerative LIC 30 is a battery whose capacity is lower than the total capacity of the lithium ion capacitors 21 to 26. The regenerative LIC 30 has, for example, one third of the total capacity of the lithium ion capacitors 21 to 26, i.e., the capacity of any two of the lithium ion capacitors 21 to 26. More specifically, the regenerative LIC 30 may include two lithium ion capacitors that are the same as the lithium ion capacitors 21 to 26 and that are connected in series. Alternatively, part of the lithium ion capacitors 21 to 26 of the power supply device 10 may be used as the regenerative LIC 30. The regenerative LIC 30 serves as an exemplary “second battery”.

The FET switch 112 is connected to the lithium ion capacitor 20. The FET switch 112 is connected to the charge circuit 101 via a charge path 203. The FET switch 112 is a switch for connecting the charge path 203 to the lithium ion capacitor 20 in order to charge the lithium ion capacitor 20. The FET switch 112 is turned on under the control of a charge controller 121. When the FET switch 112 is on, the charge path 203 is connected to the lithium ion capacitor 20 and electricity that is output from the charge circuit 101 is sent to the lithium ion capacitor 20.

The FET switch 111 is connected to the FET switch 112. The FET switch 111 is connected to the diagnosis circuit 103 and the controller 11. The FET switch 111 is a switch for connecting a discharge path 201 to the lithium ion capacitor 20 for discharge from the lithium ion capacitor 20. The FET switch 111 is turned on under the control of a life diagnosis controller 122 or a backup discharge controller 124. When the FET switch 111 is on, the discharge path 201 is connected to the lithium ion capacitor 20 and the electricity that is output from the lithium ion capacitor 20 is sent to the controller 11 or the diagnosis circuit 103.

The FET switch 131 is a switch for connecting the lithium ion capacitors 21 and 24 to the regenerative LIC 30. The FET switch 131 is turned on under the control of a balancing discharge controller 123. When the FET switch 131 is on, the lithium ion capacitors 21 and 24 are connected to the regenerative LIC 30. The lithium ion capacitors 21 and 24 discharge and the discharged electricity is sent to the regenerative LIC 30.

The FET switch 132 is a switch for connecting the lithium ion capacitors 22 and 25 to lithium ion capacitors the regenerative LIC 30. The FIT switch 132 is turned on under the control of the balancing discharge controller 123. When the FET switch 132 is on, the lithium ion capacitors 22 and 25 are connected to the regenerative LIC 30. The lithium ion capacitors 22 and 25 then discharges and the discharged electricity is sent to the regenerative LIC 30.

The FET switch 133 is a switch for connecting the lithium ion capacitors 23 and 26 to the regenerative LIC 30. The FIT switch 133 is turned on under the control of the balancing discharge controller 123. When the FET switch 133 is on, the lithium ion capacitors 23 and 26 are connected to the regenerative LIC 30. The lithium ion capacitors 23 and 26 discharge and the discharged electricity is sent to the regenerative LIC 30.

The charge circuit 101 is a circuit for charging the lithium ion capacitor 20. The charge circuit 101 is connected to the FET switch 112 via the charge path 203. The charge circuit 101 is connected to the controller 11 via a charge path 202.

The charge circuit 101 is supplied with electricity that is output from the controller 11 or the booster circuit 104. The charge circuit 101 converts the supplied electricity to a constant current and a constant voltage under pulse width modulation (PWM) control from the charge controller 121. The charge circuit 101 sends the electricity with the constant voltage and the constant current to the lithium ion capacitor 20 via the FET switch 112 and charges the lithium ion capacitor 20 with the constant current and the constant voltage.

The booster circuit 104 is, for example a DC (direct current)/DC converter. The booster circuit 104 boosts the voltage of the input electricity to around the charge voltage of the lithium ion capacitor 20. The booster circuit 104 then sends the boosted power to the charge circuit 101 via the charge path 202. The booster circuit 104 sends the boosted electricity to the diagnosis circuit 103.

The diagnosis circuit 103 performs life diagnoses on the lithium ion capacitor 20 and the regenerative LIC 30. The diagnosis circuit 103 has in advance a backup LIC threshold that is a flag of the internal resistance and the capacitance of the lithium ion capacitor 20. The diagnosis circuit 103 further has in advance a regenerative LIC threshold that is a threshold of the internal resistance and capacitance of the regenerative LIC 30.

For a life diagnosis on the lithium ion capacitor 20, the diagnosis circuit 103 connects the discharge path 201 to the regenerative LIC 30 under the control of the life diagnosis controller 122. The diagnosis circuit 103 then receives an input of electricity discharged from the lithium ion capacitor 20. The diagnosis circuit 103 then calculates an internal resistance and a capacitance of the lithium ion capacitor 20 by using the input electricity. The diagnosis circuit 103 outputs the electricity used for the diagnosis to the regenerative LIC 30 to charge the regenerative LIC 30.

The diagnosis circuit 103 then determines whether the calculated internal resistance and capacitance of the lithium ion capacitor 20 is equal to or larger than the backup LIC threshold. When the internal resistance and capacitance of the lithium ion capacitor 20 is equal to or larger than the backup LIC threshold, the diagnosis circuit 103 issues an alarm notifying deterioration of the lithium ion capacitor 20 to the controller 11. The controller 11 transmits this alarm to the server 3 to notify the operator of the deterioration of the lithium ion capacitor 20. In response to this notification, the operator performs processing for, for example, replacement of the lithium ion capacitor 20. The diagnosis circuit 103 further notifies the charge controller 121 of completion of diagnosis of the lithium ion capacitor 20.

On the other hand, when the internal resistance and capacitance of the lithium ion capacitor 20 is smaller than the backup LIC threshold, the diagnosis circuit 103 notifies the charge controller 121 of completion of diagnosis of the lithium ion capacitor 20.

For a life diagnosis on the regenerative LIC 30, the diagnosis circuit 103 receives an input of electricity that is output from the booster circuit 104 under the control of the life diagnosis controller 122. The diagnosis circuit 103 then calculates an internal resistance and a capacitance of the regenerative LIC 30 by using the input electricity. The diagnosis circuit 103 grounds the electricity used for the diagnosis.

The diagnosis circuit 103 then determines whether the calculated internal resistance and capacitance of the regenerative LIC 30 is equal to or larger than the regenerative LIC threshold. When the internal resistance and capacitance of the regenerative LIC 30 is equal to or larger than the regenerative LIC threshold, the diagnosis circuit 103 issues an alarm notifying deterioration of the regenerative LIC 30 to the controller 11. The controller 11 transmits this alarm to the server 3 to notify the operator of the deterioration of the regenerative LIC 30. In response to this notification, the operator performs processing for, for example, replacement of the regenerative LIC 30. The diagnosis circuit 103 further notifies the charge controller 121 of completion of diagnosis of the regenerative LIC 30.

On the other hand, when the internal resistance and capacitance of the regenerative LIC 30 is smaller than the regenerative LIC threshold, the diagnosis circuit 103 notifies the charge controller 121 of completion of diagnosis of the regenerative LIC 30.

The controller 102 controls the charge and discharge with respect to the lithium ion capacitor 20 and the regenerative LIC 30, controls balancing discharge in the lithium ion capacitor 20, and controls execution of life diagnoses on the lithium ion capacitor 20 and the regenerative LIC 30. The controller 102 includes the charge controller 121, the life diagnosis controller 122, a balancing discharge controller 123, and the backup discharge controller 124. The controller 102 is implemented with, for example, a microcomputer.

When the lithium ion capacitor 20 is mounted, the charge controller 121 turns on the FFT switch 112. The charge controller 121 further performs PWM control on the charge circuit 101. Accordingly, when there is a power supply from the controller 11, the lithium ion capacitor 20 is charged with a constant current and a constant voltage. The charge controller 121 then measures the voltages of the lithium ion capacitors 21 to 26. When the voltages of the lithium ion capacitors 21 to 26 are equal to or larger than a given value, the charge controller 121 determines that charging the lithium ion capacitor 20 completes and turns off the FET switch 112 to stop controlling the charge circuit 101.

The charge controller 121 receives the notification of completion of the diagnosis on the lithium ion capacitor 20 from the diagnosis circuit 103. The charge controller 121 then controls the booster circuit 104 with respect to boosting of the output voltage from the regenerative LIC 30 and outputting of the voltage to the charge circuit. The charge controller 121 turns on the FET switch 112. Under the control, the electricity that is output from the regenerative LIC 30 is boosted by the booster circuit 104 and is input to the charge circuit 101 via the charge path 202 to charge the lithium ion capacitor 20.

The charge controller 121 notifies the life diagnosis controller 122 of start of charging the lithium ion capacitor 20 by using the discharge from the regenerative LIC 30. The charge controller 121 then receives the notification of completion of the diagnosis on the regenerative LIC from the diagnosis circuit 103. The charge controller 121 controls recharging corresponding to a shortage in the lithium ion capacitor 20. Specifically, the charge controller 121 turns on the FET switch 112 to execute the PWM control on the charge circuit 101. Thereafter, when the voltages of the lithium ion capacitors 21 to 26 are equal to or larger than the given threshold and charging the lithium ion capacitor 20 completes, the charge controller 121 turns off the FET switch 112.

The charge controller 121 notifies the balancing discharge controller 123 of the execution of recharging corresponding to insufficiency. The charge controller 121 then controls the recharging of the lithium ion capacitor 20 corresponding to the insufficiency. When the voltages of the lithium ion capacitors 21 to 26 are equal to or larger than the given threshold and charging the lithium ion capacitor 20 completes, the charge controller 121 turns off the FET switch 112.

The life diagnosis controller 122 then determines whether a timing at which a constant deterioration diagnosis is performed on the lithium ion capacitor 20 comes. For example, when a given period elapses from the previous constant deterioration diagnosis, the life diagnosis controller 122 determines that the timing for a constant deterioration diagnosis comes.

When the timing for a constant deterioration diagnosis comes, the life diagnosis controller 122 turns on the FET switch 111 to connect the lithium ion capacitor 20 to the discharge path 201. Furthermore, the life diagnosis controller 122 controls the diagnosis circuit 103 to perform a deterioration diagnosis on the lithium ion capacitor 20. Under the control, the lithium ion capacitor 20 discharges. The electricity discharged from the lithium ion capacitor 20 is sent to the regenerative LIC 30 via the diagnosis circuit 103. Accordingly, the diagnosis circuit 103 performs a deterioration diagnoses on the lithium ion capacitor 20. Furthermore, the regenerative LIC 30 is charged with the electricity discharged from the lithium ion capacitor 20.

The life diagnosis controller 122 further receives, from the charge controller 121, a notification of start of charging the lithium ion capacitor 20 by using the discharge from the regenerative LIC 30. The life diagnosis controller 122 then controls the diagnosis circuit 103 to perform a life diagnose on the regenerative LIC 30. Under the control, the diagnosis circuit 103 performs a life diagnoses by using discharge from the lithium ion capacitor 20.

The balancing discharge controller 123 measures the voltage of each of the lithium ion capacitors 21 to 26 constantly. FIG. 2 representatively illustrates only an input of a signal from the lithium ion capacitor 26 to the balancing discharge controller 123; however, in practice, a signal is input from each of the lithium ion capacitors 21 to 25 to the balancing discharge controller 123.

The balancing discharge controller 123 compares the voltages of the lithium ion capacitors 21 to 26. When the difference between the voltages is equal to or larger than a given threshold, the balancing discharge controller 123 determines that a balance abnormality occurs and performs the following process. For example, a case where the voltage of the lithium ion capacitor 25 is high will be described. The balancing discharge controller 123 turns on the FET switch 132 connected to the lithium ion capacitor 25 having a high voltage among the FET switches 131 to 133 such that the difference between the voltages is smaller than the given value. Accordingly, balance adjusting discharge from the lithium ion capacitor 25 having a high voltage is performed and accordingly the voltage of the lithium ion capacitor 25 lowers. In this manner, the balancing discharge controller 123 performs control such that the voltages of the lithium ion capacitors 21 to 26 are equal to one another.

In this case, the electricity that is output from the lithium ion capacitor 25 is sent to the regenerative LIC 30 to charge the regenerative LIC 30.

The balancing discharge controller 123 receives a notification of execution of recharge corresponding to insufficiency from the charge controller 121. The balancing discharge controller 123 then controls determination on occurrence of balance abnormality and balance adjusting discharge.

When power supply from the eternal power to the storage device 1 stops due to, for example, a power failure, the backup discharge controller 124 receives an instruction for starting a backup power from the controller 11. The backup discharge controller 124 performs control to turn on the FET switch 111. Accordingly, power is supplied from the lithium ion capacitor 20 to the controller 11 via the discharge path 201. Upon receiving notification of restoring of the external power from the controller 11, the backup discharge controller 124 turns off the FET switch 111.

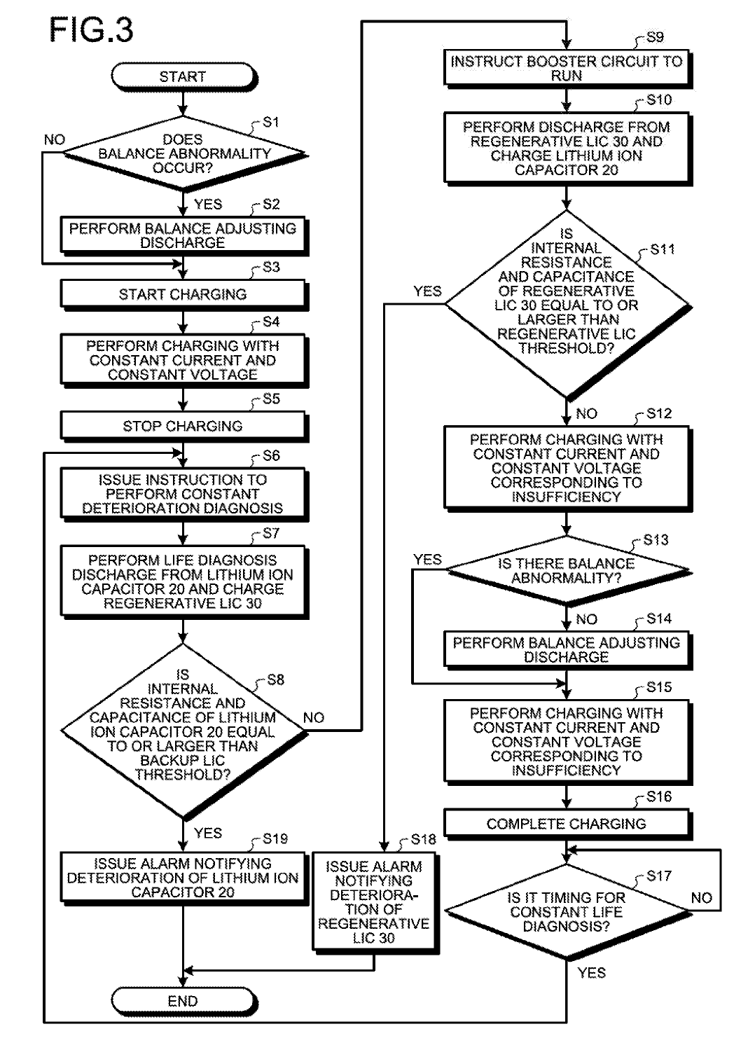

A flow of the life diagnosis process performed by the power supply device 10 according to the embodiment will be described with reference to FIG. 3. FIG. 3 is a flowchart of the life diagnosis process performed by the power device according to the embodiment. The case where the lithium ion capacitor 20 is already charged will be described here.

When the storage device 1 is powered on, the balancing discharge controller 123 measures the voltages of the lithium ion capacitors 21 to 26 and determines whether a balance abnormality occurs (step S1).

When a balance abnormality occurs (YES at step S1), the balancing discharge controller 123 performs balance adjusting discharge (step S2). Then the process proceeds to step S3.

When no balance abnormality occurs (NO at step S1) or when the balance adjusting discharge completes (step S2), the charge controller 121 turns on the FET switch 112 and performs the PWM control on the charge circuit 101 to start charging (step S3).

The charge circuit 101 is supplied with the electricity that is input from the controller 11 via the charge path 202. The charge circuit 101 then converts the supplied electricity to a constant voltage and a constant current and inputs the constant voltage and the constant current to the lithium ion capacitor 20 to charge the lithium ion capacitor 20 with the constant voltage and the constant current (step S4).

Thereafter, when the voltages of the lithium ion capacitors 21 to 26 are equal to or larger than the given value, the charge controller 121 determines that the charging completes, turns off the FET switch 112, and stops the PWM control on the charge circuit 101 to stop the charging (step S5).

When the timing for a constant deterioration diagnosis comes, the life diagnosis controller 122 turns on the FET switch 111 and instructs the diagnosis circuit 103 to execute a constant deterioration diagnosis on the lithium ion capacitor 20 (step S6).

The lithium ion capacitor 20 performs life diagnosis discharge for a life diagnosis to the discharge path 201. The electricity discharged from the lithium ion capacitor 20 to the discharge path 201 is input to the regenerative LIC 30 via the diagnosis circuit 103 to charge the regenerative LIC 30 (step S7).

The diagnosis circuit 103 uses the electricity that is discharged from the lithium ion capacitor 20 to calculate an internal resistance and a capacitance of the lithium ion capacitor 20. The diagnosis circuit 103 then determines whether the internal resistance and the capacitance of the lithium ion capacitor 20 is equal to or larger than the backup LIC threshold (step S8).

When the internal resistance and the capacitance of the lithium ion capacitor 20 is smaller than the backup LIC threshold (NO at step S8), the diagnosis circuit 103 notifies the charge controller 121 of completion of the life diagnosis on the lithium ion capacitor 20. Upon receiving the notification of completion of the life diagnosis on the lithium ion capacitor 20, the charge controller 121 instructs turns on the FET switch 112 and instructs the booster circuit 104 to run (step S9). Furthermore, the charge controller 121 performs the PWM control on the charge circuit 101.

The regenerative LIC 30 performs discharging to the booster circuit 104. The electricity discharged from the regenerative LIC 30 to the booster circuit 104 is input to the lithium ion capacitor 20 via the booster circuit 104, the charge path 202, the charge circuit 101, the charge path 203, and the FET switch 112. Accordingly, the lithium ion capacitor 20 is charged (step S10).

By using the electricity discharged from the regenerative LIC 30, the diagnosis circuit 103 calculates an internal resistance and a capacitance of the regenerative LIC 30. The diagnosis circuit 103 then determines whether the internal resistance or the capacitance of the regenerative LIC 30 is equal to or larger than the regenerative LIC threshold (step S11).

When the internal resistance and the capacitance of the regenerative LIC 30 are smaller than the regenerative LIC threshold (NO at step S11), the diagnosis circuit 103 notifies the charge controller 121 of completion of the life diagnosis on the regenerative LIC 30. Upon receiving the notification on completion of the life diagnosis on the regenerative LIC 30, the charge controller 121 turns on the FET switch 112 and performs the PWM control on the charge circuit 101 to perform charging of the lithium ion capacitor 20 with the constant current and the constant voltage corresponding to insufficiency (step S12). The charge controller 121 then instructs the balancing discharge controller 123 to perform balance adjustment.

The balancing discharge controller 123 receives an instruction for balance adjustment from the charge controller 121. The balancing discharge controller 123 measures the voltages of the lithium ion capacitors 21 to 26 and determines whether a balance abnormality occurs (step S13).

When a balance abnormality occurs (NO at step S13), the balancing discharge controller 123 performs balance adjusting discharge (step S14). The process then proceeds to step S15.

When no balance abnormality occurs (YES at step S13) or when the balance adjusting discharge completes (step S14), the charge controller 121 turns on the FET switch 112 and executes the PWM control on the charge circuit 101. Accordingly, charging of the lithium ion capacitor 20 with the constant current and the constant voltage corresponding to insufficiency is performed (step S15).

When the voltages of the lithium ion capacitors 21 to 26 are equal to or larger than the given value, the charge controller 121 determines that the charging completes, turns off the FET switch 112, and stops the PWM control on the charge circuit 101 to stop the charging (step S16).

The life diagnosis controller 122 determines whether the timing for a constant diagnosis comes (step S17). When the timing for a constant diagnosis does not come (NO at step S17), the life diagnosis controller 122 waits until the timing for a constant life diagnosis comes.

On the other hand, when the timing for a constant diagnosis comes (YES at step S17), the life diagnosis controller 122 returns to step S6 where, although it is not illustrated in the flowchart in FIG. 3, when a balance abnormality occurs before the timing for a constant life diagnosis comes, the balancing discharge controller 123 performs balancing charge. When the voltage of the lithium ion capacitor 20 lowers, the charge controller 121 executes control for charging the lithium ion capacitor 20.

On the other hand, when the internal resistance or the capacitance of the regenerative LIC 30 is equal to or larger than the reproductive LIC threshold (YES at step S11), the diagnosis circuit 103 issues an alarm that notifies deterioration of the regenerative LIC 30 (step S18). The power supply device 10 then ends the process of life diagnosis on the lithium ion capacitor 20.

When the internal resistance and the capacitance of the lithium ion capacitor 20 are equal to or larger than the backup LIC threshold (YES at step S8), the diagnosis circuit 103 issues an alarm notifying deterioration of the lithium ion capacitor 20 (step S19). The power supply device 10 then ends the process of life diagnosis on the lithium ion capacitor 20.

Upon receiving the alarm notifying deterioration of the lithium ion capacitor 20 or the regenerative LIC 30, the operator takes a measure to, for example, replace the unit that is pointed by the alarm.

As described above, the power device according to the embodiment charges the regenerative LIC with the electricity that is discharged from the backup lithium ion capacitor for a deterioration diagnosis. The electricity stored in the regenerative LIC is boosted and recharged in the backup lithium ion capacitor. Accordingly, it is possible to curb power consumption due to discharge for a deterioration diagnosis and thus reduce the power consumption of the power device.

When discharging for diagnosis is grounded, the resistance is not constant and a constant current discharge circuit is used for constant-current discharge. On the other hand, as the power device according to the embodiment performs discharging to a load with constancy that is the regenerative LIC, a constant current circuit does not have to be set and accordingly it is possible to curb the costs and space.

As the electricity discharged from the backup lithium ion capacitor is used to charge the regenerative LIC, heat generation does not occur, which enables reduction of power for air-conditioning.

According to one embodiment of the power device, the storage device, and the power device control method disclosed herein, there is an effect that it is possible to reduce power consumption.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A power device comprising:
a primary battery;
a secondary battery whose capacity is lower than that of the primary battery;
a diagnosis unit that performs a life diagnosis on the primary battery by using electricity that is discharged from the primary battery and charges the secondary battery with the electricity used for the life diagnosis; and
a charge unit that charges the primary battery with the electricity that is output from the secondary battery.

2. The power device according to claim 1, further comprising a booster unit that boosts the electricity that is output from the secondary battery,
wherein the charge unit charges the primary battery with the electricity that is boosted by the booster unit.

3. The power device according to claim 1, wherein the primary battery includes a plurality of primary batteries,
the power device further comprising a balancing discharge controller that, when there is a difference in voltage between the primary batteries, causes a balancing discharge from the primary battery such that the voltages of the primary batteries are equal and charges the secondary battery with the electricity from the balancing discharge.

4. The power device according to claim 1, wherein the diagnosing unit diagnoses the life of the second battery by using the electricity that charges the primary battery and that is output from the secondary battery.

5. The power device according to claim 1, wherein the primary battery and the secondary battery are lithium ion capacitors.

6. A storage device comprising:
a storage;
a controller that includes a volatile memory and that controls the storage by using the volatile memory;
a primary battery that supplies power to the controller when power supply from an external power to the controller stops;
a secondary battery whose capacity is lower than that of the primary battery;
a diagnosis unit that performs a life diagnosis on the primary battery by using electricity that is discharged from the primary battery and charges the secondary battery with the electricity used for the life diagnosis; and
a charge unit that charges the primary battery with the electricity that is output from the external power and the secondary battery.

7. A power device control method, comprising:
performing a life diagnosis on a primary battery by using electricity that is discharged from the primary battery and charging a secondary battery whose capacity is lower than that of the primary battery by using the electricity used for the life diagnosis; and
charging the primary battery with the electricity that is stored in the secondary battery.
